(19) United States
(12) Patent Application Publication
(10) Pub. No.: US 2022/0158160 A1
(43) Pub. Date: May 19, 2022

(54) FLUORINATION OF AL2O3 COATING FOR LITHIUM-ION BATTERY

(71) Applicant: The Curators of the University of Missouri, Columbia, MO (US)

(72) Inventors: Xinhua LIANG, Rolla, MO (US); Han YU, Rolla, MO (US)

(21) Appl. No.: 17/602,827

(22) PCT Filed: May 11, 2020
(86) PCT No.: PCT/US2020/032299

§ 371 Date: Oct. 11, 2021

Related U.S. Application Data
(60) Provisional application No. 62/847,544, filed on May 14, 2019.

(51) Int. Cl. H01M 4/04; H01M 10/0525; C23C 16/455; C23C 16/40; H01M 4/1391; H01M 4/36; H01M 4/62; H01M 10/42

(52) U.S. Cl. CPC H01M 4/0428; H01M 10/0525; C23C 16/45555; H01M 10/4235; H01M 4/1391; H01M 4/366; H01M 4/628; C23C 16/403

(57) ABSTRACT

Improving the performance of cathodes by using surface coatings has proven to be an effective method for improving the stability of Li-ion batteries (LIBs), while a high-quality film satisfying all requirements of electrochemical inertia, chemical stability, and lithium ion conductivity has not been found. Disclosed herein is a composite film composed of A₂O₃ and AlF₃ layers was coated on the surface of Li_{1.2}Mn_{0.54}Co_{0.13}Ni_{0.13}O₂ (Li-rich NMC) based electrodes by atomic layer deposition (ALD). By varying the ratio of Al₂O₃ and AlF₃, an optimal coating was achieved. The electrochemical characterization results indicated that the coating with 1 cycle of AlF₃ ALD on 5 cycles of Al₂O₃ ALD (1AlF₃—5Al₂O₃) significantly improved the cycling stability and alleviated the voltage attenuation problem of Li-rich NMC based electrodes by suppressing side reactions between the electrolyte and electrode, as well as inhibiting the transformation of layered Li₂MnO₃ into a spinel-like phase. After 200 cycles of charge-discharge, the discharge capacity retention of LIB half cells based on 1AlF₃—5Al₂O₃ coated Li-rich NMC electrodes kept at 84%, much higher than that of the uncoated Li-rich NMC (the capacity retention less than 20%).

### CROSS-REFERENCE TO RELATED APPLICATIONS

This application is a U.S. national application under 37 C.F.R. § 371(b) of International Application No. PCT/US2020/032299 filed May 11, 2020, which claims the benefit under 35 U.S.C. § 119(e) to U.S. Provisional Patent Application No. 62/847,544 filed on May 14, 2019, the disclosures of which are incorporated herein by reference in their entirety.

### FIELD OF THE INVENTION

The present disclosure relates generally to the field of lithium-ion batteries, and particularly to coating the surfaces of electrodes and/or particles with films (or coatings) using atomic layer deposition (ALD) techniques to provide thin-film coated electrodes and/or particles possessing enhanced stability and significantly improved electrochemical performance.

### BACKGROUND AND SUMMARY OF THE INVENTION

Improving the performance of cathodes by using surface coatings has proven to be an effective method for enhancing the stability of Li-ion batteries (LIBs). However, a high-quality film satisfying all requirements of electrochemical inertia, chemical stability, and lithium ion conductivity has not been found to-date.

As one of the main power sources of portable electronic devices, rechargeable Li-ion batteries (LIBs) are very important in daily life. With a wider range of applications, such as electric vehicles, LIBs with longer cycle life and higher power density are urgently needed. Li-rich oxides with layered structure, xLi₂MnO₃.(1−x)LiMO₂(M=Mn, Co, Ni), also known as Li-rich NMC, can deliver a discharge capacity over 250 mAh/g within a voltage window of 2.0 V-4.8 V (vs. Li/Li⁺). Li-rich NMC has attracted great attention as the next-generation of cathode materials for high energy LIBs. However, Li-rich NMC suffers from several aging problems, which hinder the commercial applications. Firstly, the release of O₂ at high voltage during the first charging process results in thermal instability of the host materials. Secondly, charging to high voltage (e.g., 4.6 V-4.8 V) can worsen the decomposition of electrolyte, leading to undesirable side reactions between the active electrode and electrolyte species, resulting in the formation of solid permeable interphase (SPI) layer. Thirdly, during charge-discharge process, transition metal ions move into the Li vacant sites, causing cation disorder and structural change from layered structure to spinel structure and resulting in severe voltage fade. Fourthly, the dissolution of transition metals, such as Mn, leads to severe capacity decay.

Currently, there are attempts to commercialize the ALD process for LIB industries. These efforts are focused on the alumina ALD process, because alumina ALD can be easier to operate and is a relatively inexpensive process. However, the results of alumina ALD coating itself may not be satisfactory.

To address these problems, many strategies have been employed in attempts to improve the electrochemical performance of Li-rich NMC based batteries, including morphology control, element doping, and surface modification. Among the available strategies, the application of a surface coating (e.g., Al₂O₃, AlF₃, and AlPO₄) is considered to be an effective method by providing a stable interface between active materials and electrolyte. Coating mainly plays two roles in improving the electrochemical performance of these cathodes: prevention of direct contact between the electrode and the electrolyte, and suppression of transition metal (especially Mn) dissolution. Al₂O₃ is the most studied coating material and has been shown to suppress side reactions between electrodes and electrolyte as well as mitigate the decomposition of electrolyte. It was reported that Al₂O₃ ALD thin film coated on the surface of LiMn_{1.5}Ni_{0.5}O₄ (LMNO) electrode dramatically suppressed self-discharge effects as well as the dissolution of transition metals. AlF₃ coating could create some interaction with transition metal elements of Li-rich NMC to form a stable coating, which can promote the stability and lithium diffusion capacity of Li-rich NMC. However, normally AlF₃ coating is prepared by wet chemical methods, and the coatings are not uniform. It is believed that whether the coating is Al₂O₃ or AlF₃, the thickness of the coating should be ultra-thin (no more than about 2 nm) to get an optimal promotion. If the coating is too thick, there may be a barrier for mass transfer, although it was reported that the fluorination of Al₂O₃ contributed to the increase of discharge capacity. If the coating is too thin, it may degrade in a short time; and, normally, after 100 cycles of charge-discharge process, the protection of Al₂O₃decreased and then the host materials suffered a severe capacity fading, since HF resulted from the decomposition of electrolyte will consume the Al₂O₃ coating. In order to obtain stable performance without sacrificing the rate capacity, the coating should have the properties of chemical stability, electron conductivity, and Li ion conductivity. As most of the coating layer has one or two of those properties, it is beneficial to combine the merits of two different coatings.

It has been discovered that adding two or more coating layers to the surface of a substrate of a Li-ion battery results in improved electrochemical performance of

In an illustrative example of this strategy, a composite film composed of Al₂O₃ and AlF₃ layers was coated on the surface of Li_{1.2}Mn_{0.54}Co_{0.13}Ni_{0.13}O₂ (Li-rich NMC) based electrodes by atomic layer deposition (ALD).

It has been discovered that by varying the ratio of AlF₃ and Al₂O₃ (AlF₃/Al₂O₃) an coating that enhanced the electrochemical performance of the Li-rich NMC electrode can be achieved. The electrochemical characterization results indicated that the coating with 1 cycle of AlF₃ ALD on 5 cycles of Al₂O₃ ALD (1AlF₃—5Al₂O₃) significantly improved the cycling stability and alleviated the voltage attenuation problem of Li-rich NMC based electrodes by suppressing side reactions between the electrolyte and electrode, as well as inhibiting the transformation of layered Li₂MnO₃ into a spinel-like phase. After 200 cycles of charge-discharge, the discharge capacity retention of LIB half cells based on 1AlF₃—5Al₂O₃ coated Li-rich NMC electrodes remained at 84%, which is much higher than that of the uncoated Li-rich NMC (the capacity retention of which is less than 20%).

It has been found that adding a few cycles of AlF₃ ALD on top of alumina ALD films significantly improves the electrochemical performance of LIB electrodes. Moreover, AlF₃ ALD is also an inexpensive process that is compatible with the alumina ALD process. Coatings with optimized composition and thickness exhibit the favorable properties of both the AlF₃ coating and the Al₂O₃ coating, demonstrating effective protection for the cathode material against the attack from the electrolyte. This strategy can be used with other kinds of films to help improve the performance of LIBs with higher output voltage, higher energy density, and longer life span.

On the following pages, are described further illustrative embodiments of the invention, including detailed examples of the processes, methods, and experimental procedures of the invention, along with figures and drawings in support of the invention.

While the invention disclosed herein is being illustrated and described in detail in the figures and this entire Description, the same is to be considered as illustrative and not restrictive in character, it being understood that only selected embodiments are being shown and described and that all changes, modifications and equivalents that come within the spirit of the disclosures described heretofore or in the following, and/or defined by the claims at the end, are desired to be protected. It is understood that additions, omissions, substitutions, and other modifications can be made by those skilled in the art without departing from the scope of the present invention.

### BRIEF DESCRIPTION OF THE DRAWINGS

FIG. 1. (A) XPS spectra of UC NMC electrode and 20AlF₃ NMC electrode and (B) high resolution XPS spectra of F₁ₛ.

FIG. 2. XRD patterns of UC NMC electrode and 20AlF₃ NMC electrode. FIG. 3. Discharge performance of different cycles (A) Al₂O₃ coated NMC electrodes and (B) AlF₃ coated NMC electrodes.

FIG. 4. Discharge performance of NMC electrodes with a combination of AlF₃ and Al₂O₃ALD films.

FIG. 5. Separated discharge capacities for UC, 6Al₂O₃, 6AlF₃, 1AlF₃—5Al₂O₃, 2AlF₃—4Al₂O₃, 4AlF₃—2Al₂O₃, and 5AlF₃—1Al₂O₃ NMC electrodes at a 1 C rate in a voltage range of (A) 3.5V-4.8 V (layered) and (B) 2.0 V-3.5 V (spinel) at room temperature.

FIG. 6. Discharge voltage change of UC, 6Al₂O₃, 6AlF₃, 1AlF₃—5Al₂O₃, 2AlF₃—4Al₂O₃, 4AlF₃—2Al₂O₃, and 5AlF₃—1Al₂O₃ ALD coated NMC electrodes.

FIG. 7. First two cycles of charge-discharge curves of (A) UC NMC electrode and (B) 1AlF₃—5Al₂O₃ NMC electrode.

FIG. 8. dQ/dV plots for the first charge-discharge cycle of UC NMC electrode and 1AlF₃—5Al₂O₃ NMC electrode.

FIG. 9. XPS results of C₁ₛ of (A, C) fresh and (B, D) cycled electrodes: (A) fresh UC NMC electrode, (B) cycled UC NMC electrode, (C) fresh 1AlF₃—5Al₂O₃ NMC electrode, (D) cycled 1AlF₃—5Al₂O₃ NMC electrode; XPS results of F₁ₛ of (E,G) fresh and (F, H) cycled electrodes: (E) fresh UC NMC electrode, (F) cycled UC NMC electrode, (G) fresh 1AlF₃—5Al₂O₃ NMC electrode, (H) cycled 1AlF₃—5Al₂O₃ NMC electrode; and XPS results of Al₂ₚ of (I) fresh 1AlF₃—5Al₂O₃ NMC electrode, (J) cycled 1AlF₃—5Al₂O₃ NMC electrode.

FIG. 10. EIS profiles of (A) UC NMC and (B) 1AlF₃—5Al₂O₃ NMC, obtained at a cell potential of 2.9 V (vs Li/Li+), and (C) the simulated equivalent circuit.

FIG. 11. Summary of fitted parameters, Rf and Rct, at 0th cycle (left) 10th cycle (middle) and 100th cycle (right).

FIG. 12 Discharge performance of uncoated and coated NMC: (A) Al₂O₃ coated NMC, and (B) AlF₃—Al₂O₃ coated NMC at 1 C rate.

FIG. 13 First three cycles of cyclic voltammograms of uncoated NMC, 2Al₂O₃, and 1AlF₃—1Al₂O₃ coated NMC.

FIG. 14. Cycling performance of disassembled and reassembled 1AlF₃—1Al₂O₃ coated NMC based battery.

FIG. 15. Discharge performance of full cells based on uncoated NMC and 1AlF₃—1Al₂O₃ coated NMC and Li₄Ti₅O₁₂ (LTO) at a 1 C rate.

### DETAILED DESCRIPTION

Embodiments of the invention disclosed herein include cathode electrodes based on Li-rich NMC particles. They also include AlF₃/Al₂O₃ coatings (with various ratios) for other lithium ion battery electrode materials (including cathodes and anodes). Illustrative examples of cathode materials include, but are not limited to, LiMn_{1.5}Ni_{0.5}O₄ (LMNO), Li-rich NMC (as disclosed above), Ni-rich NMC such as LiNi_{0.6}Mn_{0.2}Co_{0.2}O₂ (NMC622) and LiNi_{0.8}Mn_{0.1}Co_{0.1}O₂ (NMC811), and the like. It is understood that the films can be coated on both particles and/or electrodes.

In another embodiment of the invention, disclosed herein is a process for coating the surface of a substrate of a Li-ion battery with a composite thin film of AlF₃ and Al₂O₃ via atomic layer deposition (ALD), the process comprising the following steps in any order: (a) coating the substrate with one or more cycles of Al₂O₃ ALD; and, (b) coating the substrate with one or more cycles of AlF₃ ALD; to obtain a substrate that is coated with the composite thin film of AlF₃ and Al₂O₃; wherein the substrate is made of one or more materials suitable for use in Li-ion batteries. Materials suitable for use in lithium ion batteries include LCO (LiCO₂), LFP (LiFePO₄), LMO (LiMn₂O₄), LMNO (LiMn_{1.5}Ni_{0.5}O₄), Li-rich NMC (Li_{1.2}Mn_{0.54}Co_{0.13}Ni_{0.13}O₂), NCA (LiNi_{0.8}Co_{0.15}Al_{0.05}O₂), a Ni-rich NMC including NMC111 (LiNi_{0.3}Mn_{0.3}Co_{0.3}O₂), NMC622 (LiNi_{0.6}Mn_{0.2}Co_{0.2}O₂), and NMC811 (LiNi_{0.8}Mn_{0.1}Co_{0.1}O₂). In one aspect of this process, the substrate is selected from an electrode and/or particles. In another aspect, when the substrate is an electrode, the electrode is selected from a cathode or an anode. In another aspect of the process, the one or more materials include one or more of LMNO (LiMn_{1.5}Ni_{0.5}O₄), Li-rich NMC (Li_{1.2}Mn_{0.54}Co_{0.13}Ni_{0.13}O₂), and Ni-rich NMC including NMC622 (LiNi_{0.6}Mn_{0.2}Co_{0.2}O₂) and NMC811 (LiNi_{0.8}Mn_{0.1}Co_{0.1}O₂). In another aspect of the process, steps (a) and/or (b) above are carried out at 100° C. In another aspect, in steps (a) and/or (b) above, the one or more cycles of ALD are in the range between 1 and 20 cycles, and preferably in the range between 1 and 5 cycles.

In another embodiment of the invention, a composition obtained by the above process is disclosed, the composition comprising: (a) the composite thin film of AlF₃ and Al₂O₃; and, (b) the substrate. In one aspect of the composition, the substrate may be either an electrode or particles. In another aspect of the composition, the substrate is made of one or more of LMNO (LiMn_{1.5}Ni_{0.5}O₄), Li-rich NMC (Li_{1.2}Mn_{0.54}Co_{0.13}Ni_{0.13}O₂), and Ni-rich NMC including NMC622 (LiNi_{0.6}Mn_{0.2}Co_{0.2}O₂) and NMC811 (LiNi_{0.8}Mn_{0.1}Co_{0.1}O₂). In another aspect of the composition, the ratio AlF₃:Al₂O₃ is in the range between about 1:8 and about 8:1, and preferably the ratio AlF₃:Al₂O₃ is about 1:5.

In another embodiment of the invention, disclosed is a method of use of the above composition to improve the cycling stability of a Li-ion battery, the method comprising the step of incorporating the composition into the Li-ion battery instead of the normally uncoated substrate of the Li-ion battery, resulting in improvement of the cycling stability of the Li-ion battery. In one aspect, the method further results in reduction of voltage attenuation of electrodes of the Li-ion battery by suppressing side reactions between the electrolyte and electrode. In another aspect, the method further results in inhibiting the transformation of layered Li₂MnO₃ into a spinel-like phase and in decreasing impedance. In another aspect, the method further results in reduction of the voltage fade problem due to aging along with the structural transformation during charge-discharge process.

Additional non-limiting embodiments of the invention are disclosed in the following clauses:

1. A process for coating the surface of a substrate of a Li-ion battery with a composite thin film of AlF₃ and Al₂O₃ via atomic layer deposition (ALD), the process comprising the following steps in any order:

(a) coating the substrate with from 1 to 10 cycles of Al₂O₃ ALD;

(b) coating the substrate with 1 to 20 cycles of AlF₃ ALD;

to obtain a substrate that is coated with the composite thin film of AlF₃ and Al₂O₃ where composite thin film has a ratio AlF₃:Al₂O₃ from about 20:1 to about 1:10; and

wherein the substrate is made of one or more materials suitable for use in Li-ion batteries.

2. The process of clause 1, wherein the substrate is an electrode or particles.

3. The process of clause 1 or 2, wherein when the substrate is an electrode, the electrode is a cathode or an anode.

4. The process of any one of the preceding clauses, wherein substrate is made of one or more of LCO (LiCO₂), LFP (LiFePO₄), LMO (LiMn₂O₄), NCA (LiNi_{0.8}Co_{0.15}Al_{0.05}O₂), LMNO (LiMn_{1.5}Ni_{0.5}O₄), Li-rich NMC (Li_{1.2}Mn_{0.54}Co_{0.13}Ni_{0.13}O₂), or a Ni-rich NMC like NMC111 (LiNi_{0.3}Mn_{0.3}Co_{0.3}O₂), NMC622 (LiNi_{0.6}Mn_{0.2}Co_{0.2}O₂), or NMC811 (LiNi_{0.8}Mn_{0.1}Co_{0.1}O₂).

5. The process of any one of the preceding clauses wherein the substrate is made from LMNO (LiMn_{1.5}Ni_{0.5}O₄) or Li-rich NMC (Li_{1.2}Mn_{0.54}Co_{0.13}Ni_{0.13}O₂) or Ni-rich NMC (LiNi_{0.6}Mn_{0.2}Co_{0.2}O₂ or LiNi_{0.8}Mn_{0.1}Co_{0.1}O₂).

6. The process of any one of the preceding clauses wherein the substrate is made from LMNO (LiMn_{1.5}Ni_{0.5}O₄).

7. The process of any one of the preceding clauses wherein the substrate is made from LMNO Li-rich NMC (Li_{1.2}Mn_{0.54}Co_{0.13}Ni_{0.13}O₂).

8. The process of any one of the preceding clauses wherein the substrate is made from the Ni-rich NMC.

9. The process of any one of the preceding clauses wherein the Ni-rich NMC is NMC622 (LiNi_{0.6}Mn_{0.2}Co_{0.2}O₂) or NMC811 (LiNi_{0.8}Mn_{0.1}Co_{0.1}O₂).

10. The process of any one of the preceding clauses wherein the Ni-rich NMC is NMC622 (LiNi_{0.6}Mn_{0.2}Co_{0.2}O₂).

11. The process of any one of the preceding clauses wherein the wherein the Ni-rich NMC is NMC811 (LiNi_{0.8}Mn_{0.1}Co_{0.1}O₂).

12. The process of any one of the preceding clauses, wherein steps (a) and/or (b) are carried out at 100° C.

13. The process of any one of the preceding clauses, wherein in step (b) the number of cycles is from 1 and 10 cycles.

14. The process of any one of the preceding clauses, wherein the number of cycles in step (a), (b), or (a) and (b) are independently in the range between 1 and 5 cycles.

15. The process of any one of the preceding clauses wherein in step (a) the number of cycles is from 1 to 2, and in step (b) the number of cycles is from 1 to 5.

16. A composition obtained by the process of any one of clauses 1 to 15.

17. The composition of clause 16, wherein the ratio AlF₃:Al₂O₃ is from about 1:8 to about 8:1.

18. The composition of clause 17, wherein the ratio AlF₃:Al₂O₃ is about 1:5.

19. Use of the composition of clause 16 to improve the cycling stability of a Li-ion battery, the use comprising the step of incorporating the composition into the Li-ion battery instead of uncoated substrate, resulting in improvement of the cycling stability of the Li-ion battery.

20 The use of clause 19, wherein the use further results in reduction of voltage attenuation of electrodes of the Li-ion battery by suppressing side reactions between the electrolyte and electrode.

21. The use of clause 19, wherein the use further results in inhibiting the transformation of layered Li₂MnO₃ into a spinel-like phase and in decreasing impedance.

22. The use of claim 19, wherein the use further results in reduction of the voltage fade problem due to aging along with the structural transformation during charge-discharge process.

It has been discovered that the merits of an ultra-thin Al₂O₃ film and AlF₃ film can be combined without sacrificing the electric conductivity, by coating different thicknesses of AlF₃ ALD films on Al₂O₃ ALD coated NMC electrodes directly. The results show that the capacity retention of 1AlF₃—5Al₂O₃ NMC (1 cycle of AlF₃ ALD on 5 cycles of Al₂O₃ ALD coated Li-rich NMC electrodes) was much higher than that of uncoated Li-rich NMC. In addition, a more stable discharge voltage indicates that the coated NMC can provide a stable power density.

### METHODS

### Li-Rich NMC Electrode Fabrication

The Li-rich NMC electrode was prepared by mixing a slurry of the Li-rich NMC powders (NEI Corp.), super P carbon black (Alfa Aesar), and poly (vinylidene fluoride) (PVDF) (Sigma Aldrich) binder in N-methyl-2-pyrrolidone (Sigma Aldrich) solvent with a weight ratio of NMC: super P: PVDF=80:10:10, and then the slurry was casted on a piece of aluminum foil. The coated foil was heated to 80° C. for 10 minutes in air and then dried overnight in a vacuum oven at 120° C. After drying, the coated foil was punched into disks with an area of 0.71 cm². A typical loading of the electrodes was about 3.5 mg cm⁻².

### Atomic Layer Deposition

Al₂O₃ and AlF₃ films were directly coated on NMC electrode disks by ALD at 100° C. Trimethylaluminum (TMA) (Sigma Aldrich) and H₂O were used as precursors for Al₂O₃ ALD. A single cycle of Al₂O₃ ALD sequence included: (1) TMA dose for 5 s, (2) wait 30 s for diffusion and reaction, (3) flush chamber with Na for 60 s to remove reaction byproducts (e.g., CH₄) and excess TMA, (4) evacuate chamber for 10 s, (5) H₂ O dose for 2 s, (6) wait 30 s for diffusion and reaction, (7) flush chamber with Na for 60 s to remove reaction byproducts and excess H₂O, and (8) evacuate chamber for 10 s. AlF₃ films were deposited on NMC electrodes by ALD with TMA and HF-pyridine (Sigma Aldrich) as precursors. The AlF₃ ALD sequence was the same as that of the Al₂O₃ ALD process. All precursors were delivered into the reactor based on their room temperature vapor pressures. In this example, 2, 4, and 6 cycles of Al₂O₃ ALD and 2, 4, 6, and 8 cycles of AlF₃ ALD were coated on NMC electrodes separately. For the composite coating, Al₂O₃ was first coated on NMC electrodes, followed by AlF₃ ALD; total 6 cycles of ALD were carried out, including x cycles of Al₂O₃ ALD followed by (6-x) cycles of AlF₃ ALD. The coated Li-rich NMC samples were name as (6-x)AlF₃₋ₓAl₂O₃NMC.

### Materials Characterizations

The uncoated and ALD coated NMC electrodes were subjected to X-ray powder diffraction analysis by Philips X-Pert multi-purpose diffractometer (MPD) using Cu Ka radiation with 2 q ranging from 5° to 90° at a scanning rate of 2.8° min⁻¹. A Kratos 165 XPS Scanning Microprobe (Physical Electronics) with a monochromated AlK α source was used for the surface composition analysis.

### Electrochemical Testing

CR2032-type coin cells were assembled in an Ar-filled dry glove box. Li metal foil was used as counter electrode in half cells. A 1.0 M solution of LiPF₆ dissolved in a mixture of ethylene carbonate (EC) and dimethyl carbonate (DMC) (1:1 in volume) (Sigma Aldrich) was used as electrolyte. A porous polypropylene (PP)/polyethylene (PE)/PP tri-layer film (Celgard Inc.) was used as separator. Galvanostatic charge-discharge cycling was performed on a battery station (Neware Corp.) over a potential range 2.0 V-4.8 V (vs. Li/Li⁺) at 25° C. at a current density of 0.05 C (1 C=250 mAh/g) for the first two cycles and 1 C for the subsequent cycles. AC impedance measurements were performed using a signal with amplitude of 5 mV over a frequency range from 500 kHz to 10 mHz. AC impedance spectra were recorded at an open circuit voltage of ˜2.9 V (vs. Li/Li⁺).

### Results

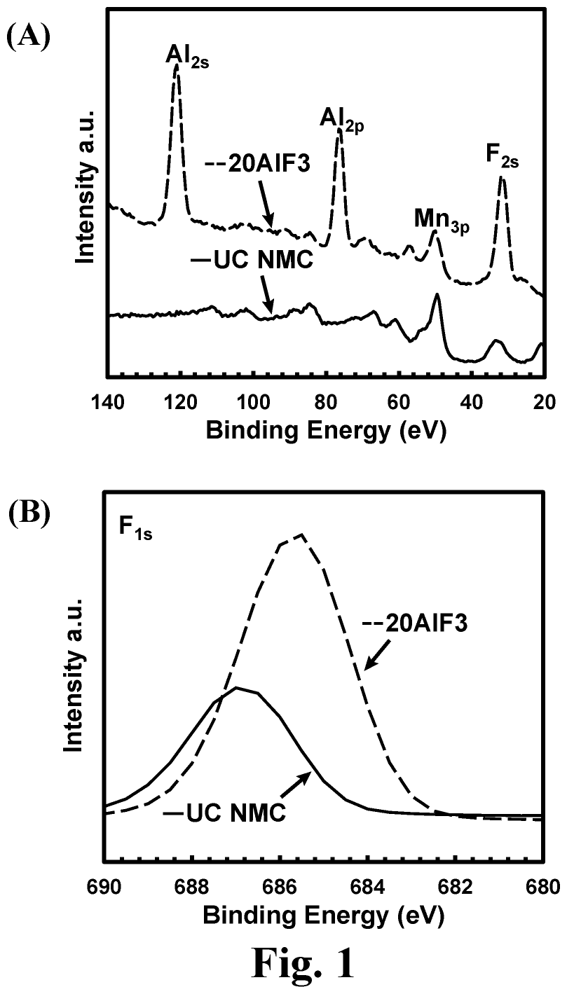

For ease of characterization, a NMC electrode was deposited with 20 cycles of AlF₃ ALD. To identify the existence of AlF₃ film, the surface compositions of the uncoated NMC electrode (UC NMC) and 20 cycles AlF₃ coated NMC (20AlF₃ NMC) electrodes were analyzed by XPS, as showed in FIG. 1. Although Al foil was used as the current collector, there was no peak belonging to Al on the UC NMC electrode, so Al foil had no influence on XPS results. For 20AlF₃ NMC, there were two strong peaks at 120 eV and 77 eV belonging to Al₂ₛ and Al₂ₚ, respectively, and the peak at 31 eV belonged to F₂ₛ. FIG. 1b shows a high resolution XPS spectrum of F₁ₛ; the peak at 687.1 eV belonged to PVDF and the peak at 685.9eV was related to metal fluoride (AlF₃). These results confirmed the formation of AlF₃on the surface of NMC electrodes by ALD.

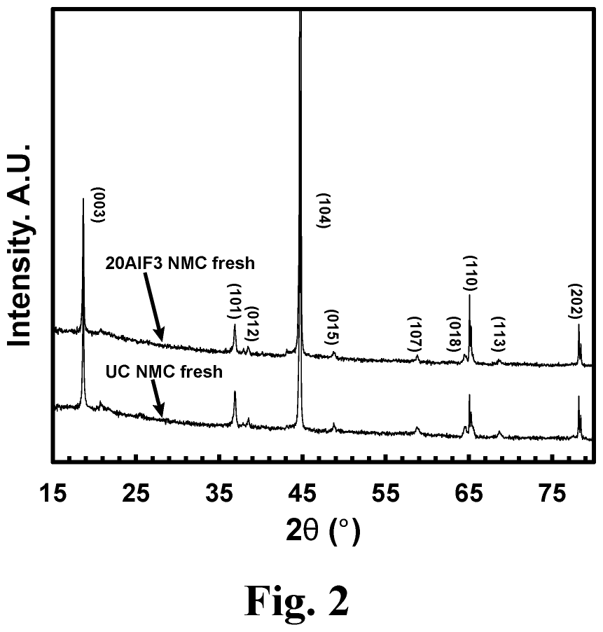

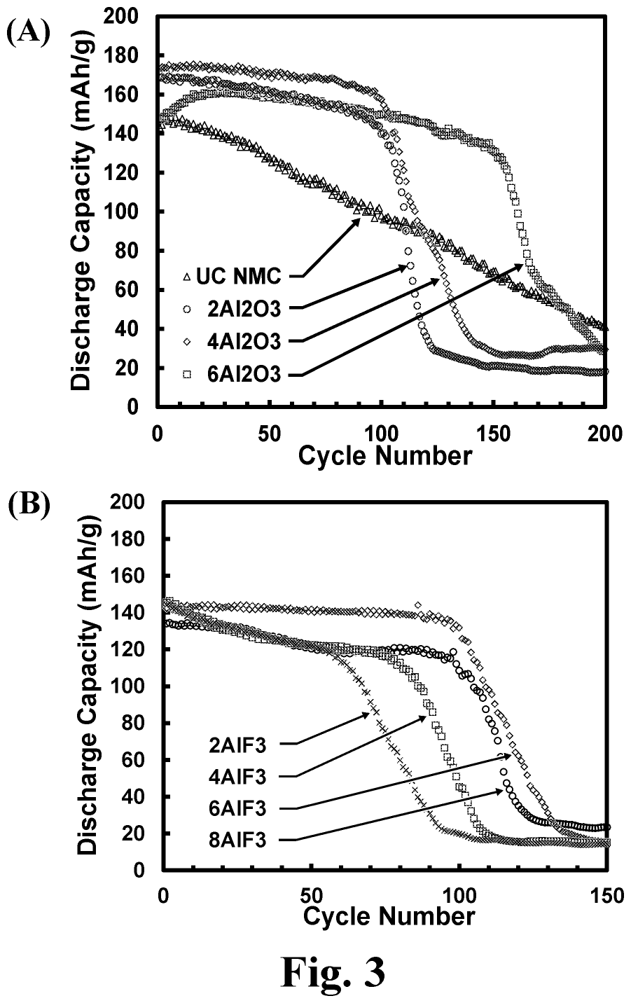

FIG. 2 shows the XRD patterns of the UC NMC and 20AlF₃ NMC electrodes. All the diffraction peaks of both materials can be indexed as NMC with hexagonal α-NaFeO₂ structure. The strong peaks of the two patterns at 45° belonged to Al foil. The XRD patterns of UC NMC and 20AlF₃ NMC were very similar, indicating that the AlF₃ coating did not affect the bulk structure of NMC. In addition, no diffraction peaks from AlF₃ were observed in the XRD pattern due to the amorphous state of AlF₃.

Different cycles of Al₂O₃ or AlF₃ were coated on the NMC electrodes to get an optimal thickness of coating. The electrochemical cycling performance based on these electrodes is showed in FIG. 3. FIG. 3a shows the discharge performance at a 1 C rate between 2.0 V and 4.8 V for the cells based on UC, 2Al₂O₃, 4Al₂O₃, and 6Al₂O₃ coated NMC electrodes at room temperature up to 200 cycles of charge-discharge. The UC NMC delivered an initial discharge capacity of ˜148 mAh/g at a 1 C rate, but the capacity kept fading along with the cycling process; after 200 cycles, the capacity declined to ˜40 mAh/g; the decline of capacity may be due to the formation of SPI and migration and dissolution of transition metals. For the 2Al₂O₃ NMC and 4Al₂O₃ NMC electrodes, the initial discharge capacity was ˜168 mAh/g and ˜172 mAh/g, respectively; after 100 cycles of charge-discharge, the discharge capacity remained at ˜142 mAh/g and ˜158 mAh/g, respectively. The increase of discharge capacities of the 2Al₂O₃ NMC and 4Al₂O₃ NMC electrodes, compared to that of UC NMC, was attributed to the formation of Li—A—O film during charge-discharge process. However, the capacity of 2Al₂O₃ NMC and 4Al₂O₃ NMC faded to ˜20 mAh/g and ˜28 mAh/g after 150 cycles of charge-discharge. These results indicated that the Al₂O₃ coating can enhance the charge-discharge capacity as well as the cycling stability to some level, but it cannot provide a long time protection. The initial discharge capacity of 6Al₂O₃ NMC was ˜147 mAh/g, which was relatively low, compared to those of 2Al₂O₃ NMC and 4Al₂O₃ NMC; this was because of the polarization with a thicker film of insulting Al₂O₃. The thicker coating layer can provide a longer time of protection, so the capacity remained at ˜137 mAh/g after 150 cycles of charge-discharge; but after that, 6Al₂O₃ NMC electrode suffered the same problem as 2Al₂O₃ NMC electrode and 4Al₂O₃ NMC electrode did. The severe decline of capacity indicated that the coating layer could be depleted by HF from electrolyte.

FIG. 3b shows the discharge performance of the cells based on 2AlF₃, 4AlF₃, 6AlF₃, and 8AlF₃ coated NMC electrodes at room temperature at a 1 C rate between 2.0 V and 4.8V. Similar to those of the Al₂O₃ coated electrodes, all AlF₃ coated NMC electrodes showed a short stability enhancement, compared to the performance of the uncoated electrodes. Among them, 6AlF₃ NMC electrodes showed the best performance with an initial capacity of ˜143 mAh/g; after 90 cycles of charge-discharge, the capacity remained at ˜140 mAh/g with a capacity retention over 95%. The performance of AlF₃ coating was consistent with a previous report that the AlF₃ coating can effectively alleviate the voltage fade in Li-rich NMC materials. However, after less than 100 cycles of charge-discharge, all electrodes suffered sharply capacity decay.

Although surface modification with Al₂O₃ or AlF₃ have achieved some success in enhancing different aspects of electrochemical performance., Al₂O₃ coating can enhance the capacity by formation of conductive Li—A—O film, while the coating layer can't resist corrosive of HF from electrolyte. AlF₃ coating can suppress the voltage fade in Li-rich NMC. Described herein is the discover that coating an ultra-thin film of Al₂O₃ on NMC electrodes enhances the surface stability without sacrificing electron conductivity between host material and carbon black, followed by a few cycles of AlF₃ ALD films applied on the uniform Al₂O₃ film surface enhances the chemical stability of the coating, while also taking advantage of the weak interaction between AlF₃ and transition metal elements of Li-rich NMC to enhance the lithium diffusion ability in Li-rich NMC.

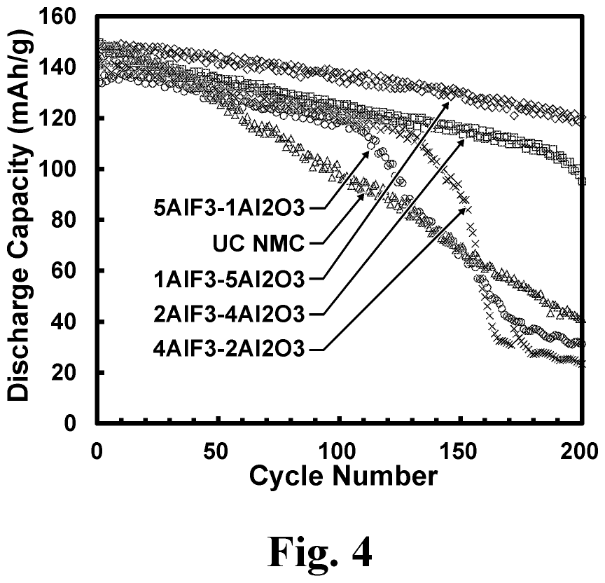

FIG. 4 shows the performance of discharge cycling at a 1 C rate between 2.0 V and 4.8 V for the cells based on UC, 1AlF₃—5Al₂O₃, 2AlF₃—4Al₂O₃, 4AlF₃—2Al₂O₃ , and 5AlF₃—1Al₂O₃ coated NMC electrodes at room temperature up to 200 cycles of charge-discharge. The 1AlF₃—5Al₂O₃ sample showed the best performance. The initial discharge capacity of 1AlF₃—5Al₂O₃ and 2AlF₃—4Al₂O₃ was ˜147 mAh/g and ˜143 mAh/g, respectively; after 200 cycles of charge-discharge, the discharge capacity still remained at ˜95 mAh/g and ˜120 mAh/g, respectively. The capacity retention of the 1AlF₃—5Al₂O₃ electrode was about 84%, compare to 25% of the uncoated NMC electrode after 200 cycles of charge-discharge. With the increase in the amount of AlF₃ coated on Al₂O₃ layer, the performance of 4AlF₃—2Al₂O₃ and 5AlF₃—1Al₂O₃ samples was more like that of pure AlF₃ coated NMC.

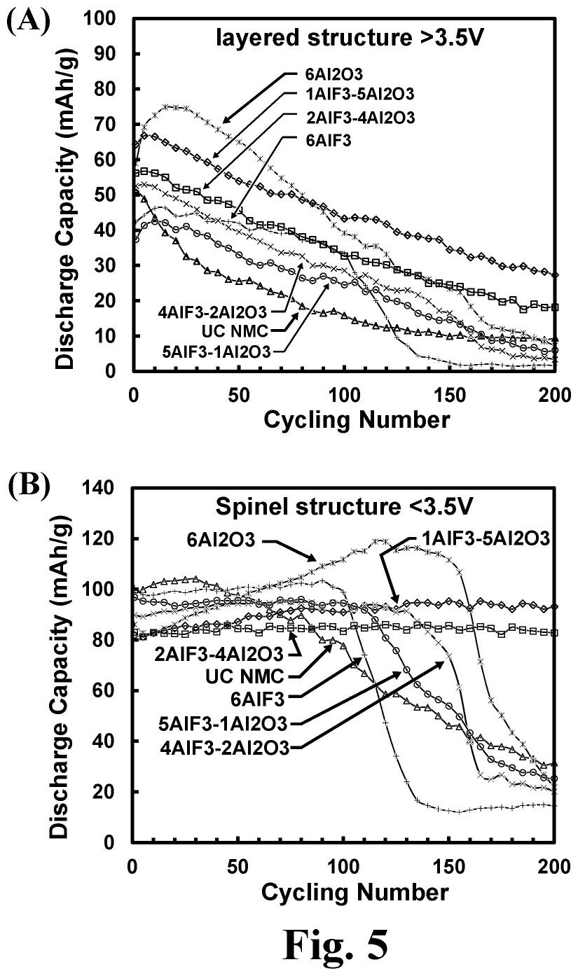

For layered Li-rich NMC, during charge-discharge process, the layered structural NMC may gradually transform to spinel structure with the increase of cycle number. In order to investigate and determine the capacity degradation of the electrodes, the discharge capacities of the uncoated and coated electrodes were separated into two parts (see FIG. 5), i.e., “>3.5 V” and “<3.5 V”. It is believed that the capacity above 3.5 V is mainly from the layered structure and the capacity below 3.5 V is mainly from the spinel structure. FIG. 5a shows the capacities provided by a layered structure. The capacities of UC NMC and 6Al₂O₃ NMC electrodes increased slightly during the initial few cycles of charge-discharge, and then kept fading along with the charge-discharge process. The capacities of 6AlF₃, 1AlF₃—5Al₂O₃, and 2AlF₃—4Al₂O₃ coated NMC electrodes kept decreasing, but slower compared to those of UC NMC and 6Al₂O₃ NMC electrodes. FIG. 5b shows the discharge capacities provided by spinel structure below 3.5V. For UC NMC, the discharge capacity showed a similar tendency with layered structure, slightly increased during the first few cycles and then kept decreasing. For 6Al₂O₃ NMC, the capacity increased from ˜83 mAh/g to ˜120 mAh/g for the first 150 cycles and then severely decreased. The increase of capacity should be related to the structure transition from the layered to a spinel-like phase in Li-Rich NMC during its repeated charge-discharge cycling. Accompanied by the migration of transition-metal cation into Li vacant sites, the working voltage inevitably decayed. However, for the 6AlF₃ NMC electrode, the capacity of spinel-like structure and layered structure remained unchanged for the first 100 cycles. The results of these two figures indicate that the AlF₃ coating not only inhibited the side reactions between active material and electrolyte, but also mitigated the transition metal ions moving to lithium vacant sites, which could suppress the structure transition from layered structure to spinel-like structure. For the 2AlF₃—4Al₂O₃ NMC electrode, the capacity of spinel-like structure kept unchanged for 200 cycles (-82 mAh/g), and the capacity of 1AlF₃—5Al₂O₃ NMC electrode showed a slightly increase for the first 200 cycles, from ˜80 mAh/g to ˜91 mAh/g.

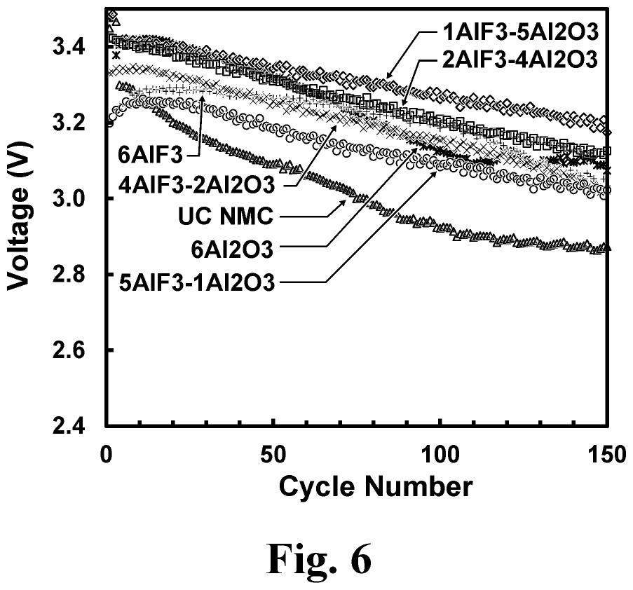

For Li-rich NMC, voltage fade is another aging problem along with the structural transformation during charge-discharge process. The average discharge voltage of UC NMC and all ALD coated NMC electrodes was calculated by dividing discharge energy by discharge capacity. FIG. 6 shows the discharge voltage of UC NMC and ALD coated NMC electrodes during the charge-discharge process. For all electrodes, the average discharge voltage of the first two cycles are nearly the same, up to 3.5 V, however, after formation, the UC NMC electrode suffered severe voltage fade during subsequent charge-discharge process when charged at a 1 C rate, the voltage kept fading from 3.3 V to 2.9 V after 150 cycles of charge-discharge. It has been reported that the activated Mn³⁺/Mn⁴⁺ and Co²⁺/Co³⁺ redox couples resulted from oxygen releasing played a critical role in voltage fade. However, for the 1AlF₃—5Al₂O₃ NMC electrode, the voltage fading is much slower than that of UC NMC; after 150 cycles of charge-discharge at a 1 C rate, the discharge voltage changed from 3.4 V to 3.2 V, which indicated that the 1AlF₃—5Al₂O₃ coating could suppress oxygen release to provide a higher power density than UC NMC did. Both enhancement of capacity retention and discharge voltage indicated that fluorination of the Al₂O₃ coating resulted in a coating with the benefits of both an Al₂O₃ coating and an AlF₃ coating.

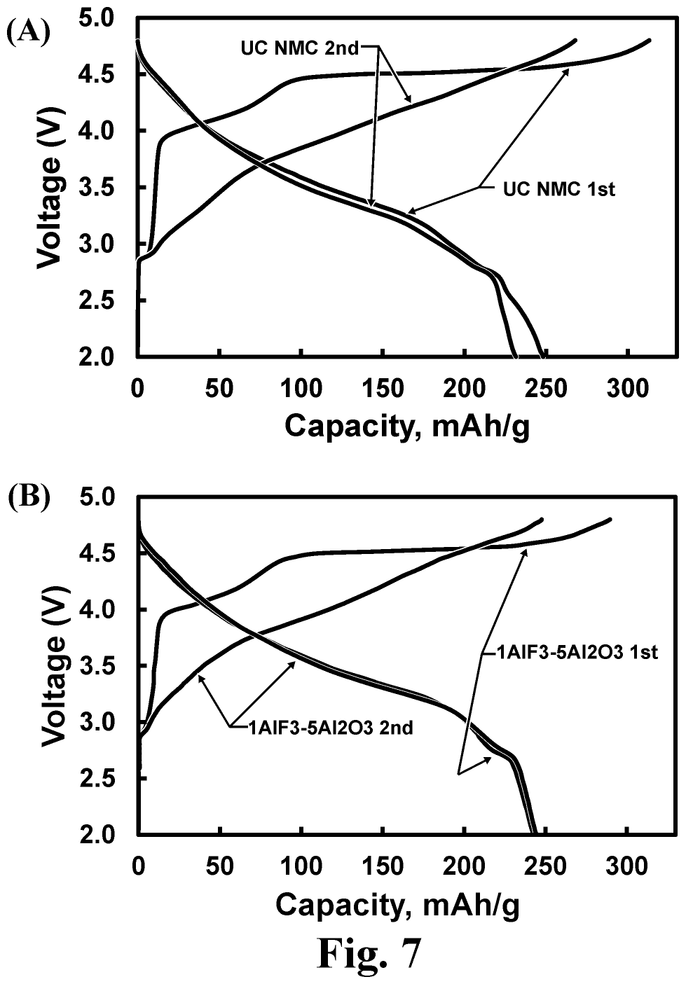

In order to understand how coating enhanced the electrochemical performance of NMC, the initial charge-discharge performance of 1AlF₃—5Al₂O₃ NMC electrodes and UC NMC and the change of interfacial layer between electrode and electrolyte after cycling was studied. The initial charge-discharge curves of the UC NMC and 1AlF₃—5Al₂O₃ NMC electrodes are shown in FIG. 7. The electrochemical performance was measured at a 0.05 C rate with a cut-off potential of 2.0 V-4.8 V. For both samples, there was a long potential platform around 4.5 V (vs. Li/Li⁺) during the first charge process, and the platform disappeared in the subsequent charge profiles. The reaction mechanism of the initial charge process was reported as the result of lithium ion extracted as Li₂O irreversibly. The initial charge capacity of the 1AlF₃—5Al₂O₃ NMC electrode was slightly lower than that of UC NMC, while the discharge capacity of the second cycle remained nearly unchanged for the coated sample. The Coulombic efficiencies of the initial charge-discharge capacities of the UC and 1AlF₃—5Al₂O₃ electrodes were 79.2% and 83.8%, respectively, while the coulombic efficiency of the second cycle of oxides coated NMC was 98.8%, much higher than that of the UC NMC, which was only 86.4%. The release of Li₂O is irreversible, which leads to lithium vacant sites, resulting in the migration of transition metal ions (e.g., Ni⁴⁺) and voltage fading during charge-discharge process. However, the lower charge capacity of the first cycle of the 1AlF₃—5Al₂O₃ NMC electrode indicated that the coating layer could mitigate the release of Li₂O.

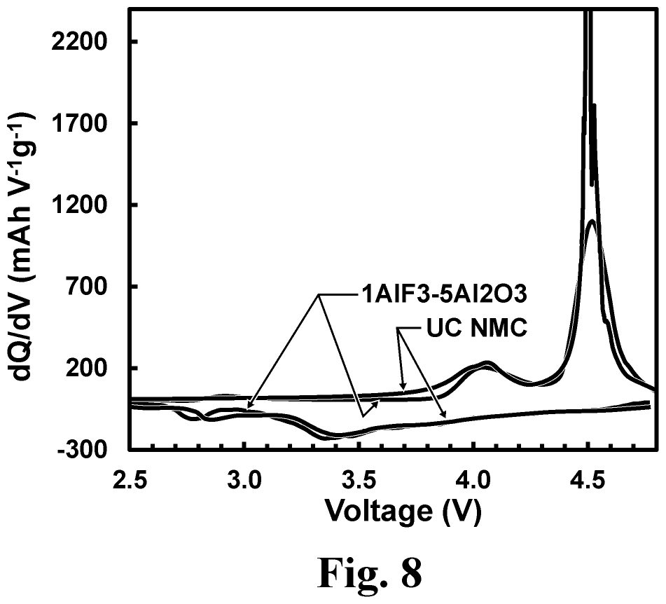

The dQ/dV curves of the first charge-discharge cycle of the UC NMC and the 1AlF₃—5Al₂O₃ NMC electrodes are shown in FIG. 8. For both samples, the charge peak at around 4.1 V corresponds to the oxidation of Ni²⁺ to Ni⁴⁺. Another sharp peak at 4.5 V is attributed to the removal of oxygen from the crystal structure, which are distinctive resultants of the activation of the Li₂MnO₃ phase. The much stronger peak of the UC NMC electrode, compared to that of the 1AlF₃—5Al₂O₃ NMC electrode at 4.5V, indicates more oxygen release during the first charging process.

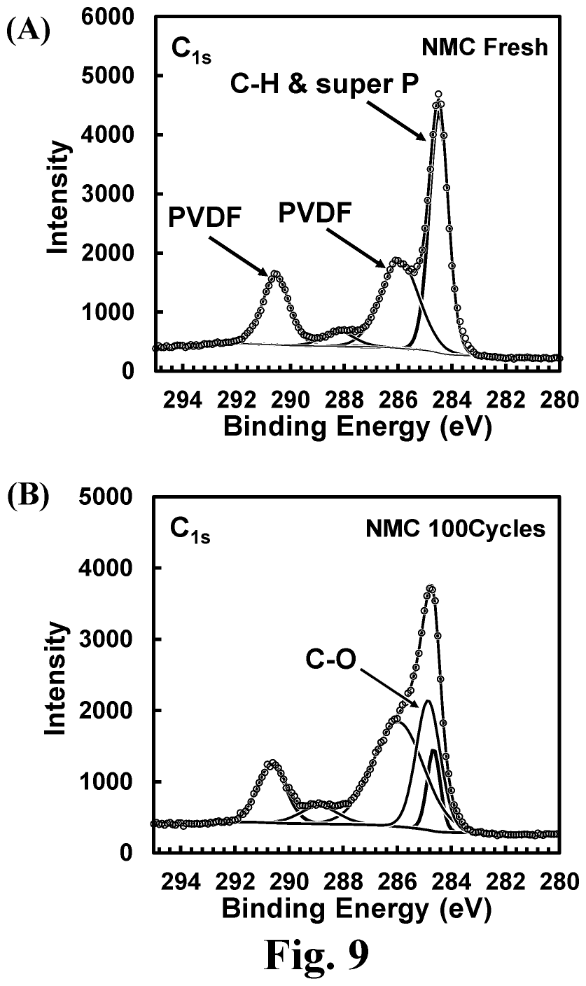

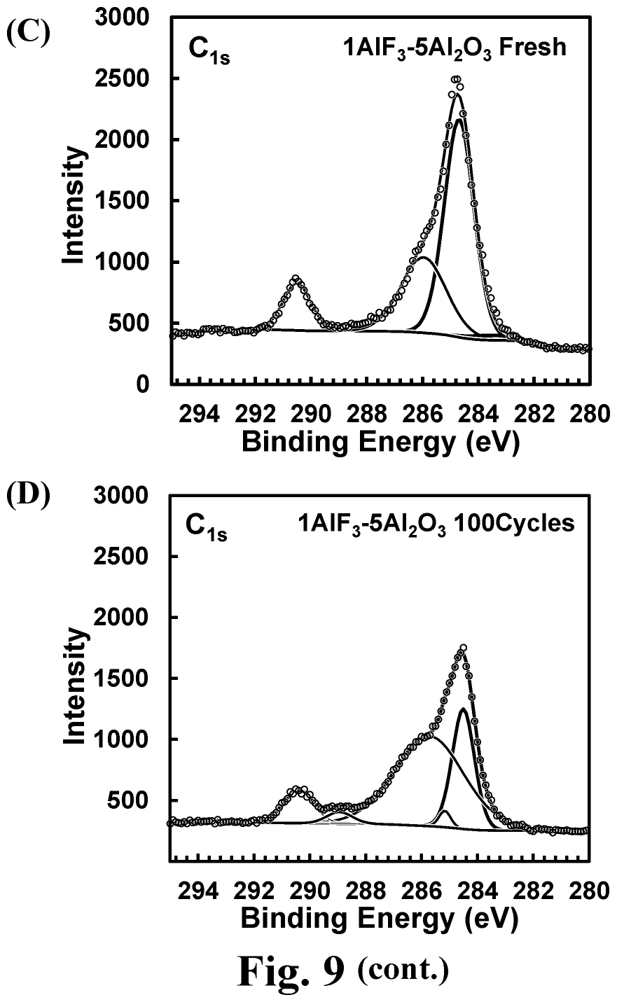

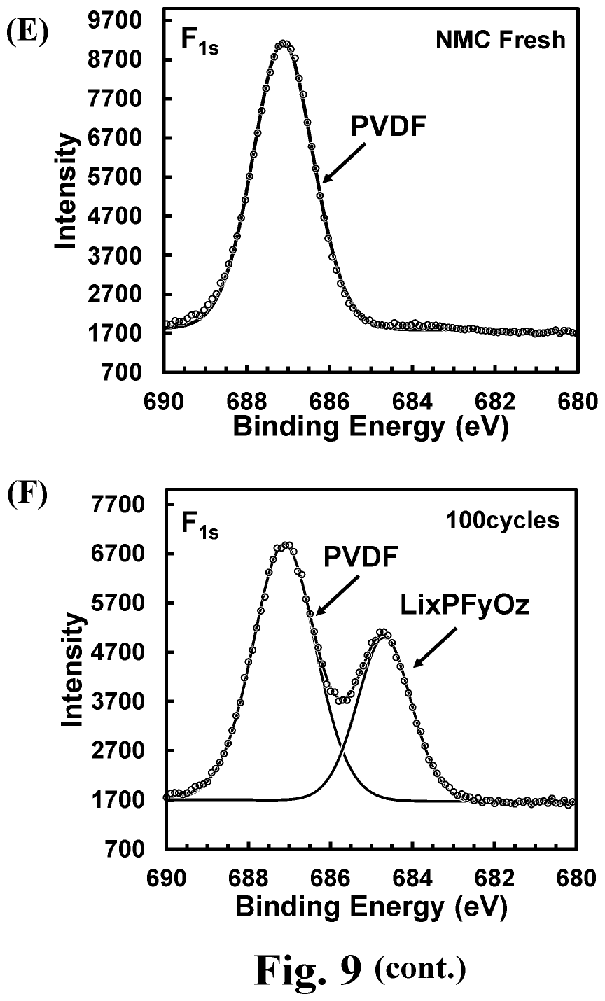

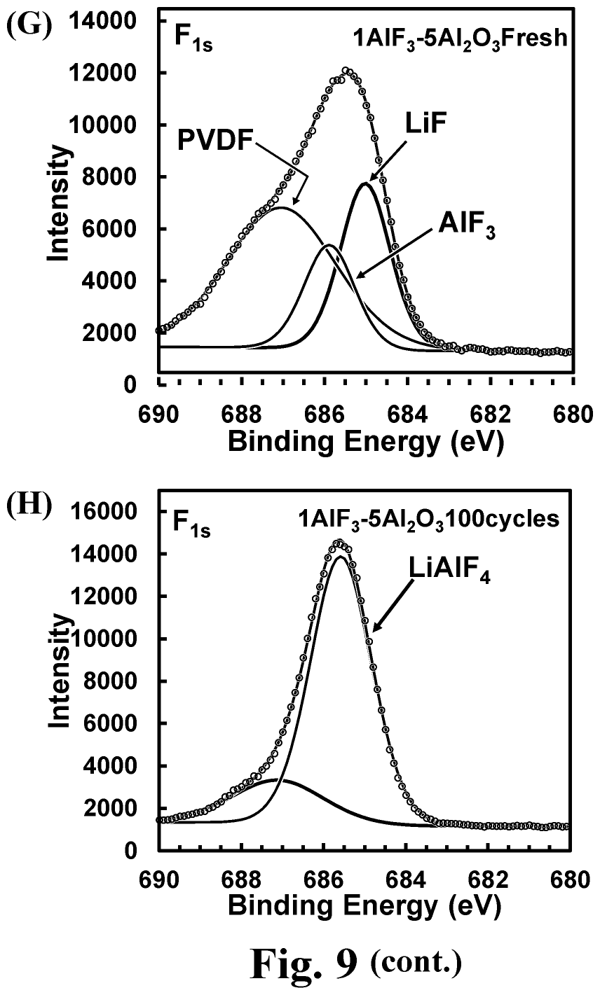

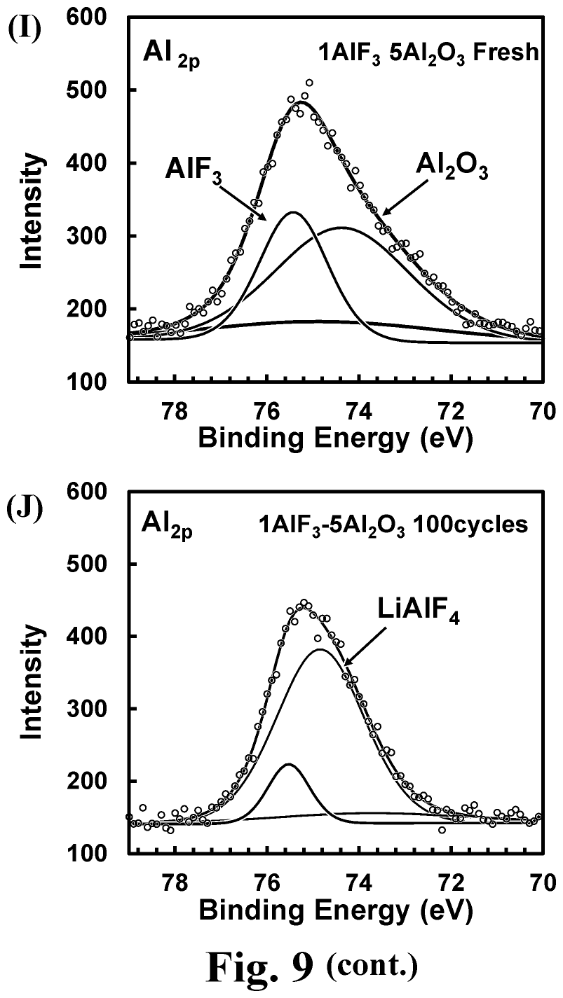

To further understand the effects of ALD surface modification on the electrochemical performance of the electrodes, the surface compositions of the fresh UC NMC, 1AlF₃—5Al₂O₃ NMC electrodes, and the electrodes after 100 cycles of charge-discharge were analyzed using XPS. In the C₁ₛ XPS spectra (FIG. 9a-d), several peaks corresponding to the CF₂ (290.5 eV) and CH₂ (285.9 eV) bonds in PVDF and the C—C bonds (284.5 eV) in super P conductive agent could be observed in both fresh UC NMC (FIG. 9a) and fresh 1AlF₃—5Al₂O₃ NMC (FIG. 9c); these two spectra shared similar peaks at the same positions. After charge-discharge for 100 cycles, a sharp peak of C—O single bond at the binding energy of 285.1 eV was observed on UC NMC, which can be attributed to carbonaceous species, mainly from the deposition of electrolyte. Furthermore, the peak value of the super P conductive agent dropped significantly for UC NMC, indicating that a very thick layer of degradation species covered on the surface of electrode; however, the peaks of PVDF did not show a sharp drop, indicating that the degradation of the electrolyte preferably involved the electrode portion where the electrochemical reaction took place. Since the carbonaceous species are unfavorable components of SPI due to their insulation and instability, we can conclude that one reason of the capacity decay of UC NMC was related to the increase of surface impedance due to the deposition of non-conductive SPI. On the other hand, there are no distinct additional peaks in the Cis spectra after 100 cycles of charge-discharge, which confirmed the chemical inert of the coating layer and the effective inhibition of the side reactions by the coating.

FIG. 9e-h illustrate the Fis XPS spectra. Only one type of fluorine (PVDF at 687.1 eV) was observed on UC NMC. However, three types of fluorine were found on the 1AlF₃—5Al₂O₃ NMC electrode. In addition to PVDF and AlF₃, another peak at 685.0 eV belongs to LiF, indicating that the dosed HF precursor could react with the host materials during the ALD process. Furthermore, after cycling, an additional peak at 684.6 eV was observed on the F₁ₛ XPS spectrum of UC NMC. This peak is generally assigned to LiₓPF_{y}LiₓPF_{y}O_{z}, which can be attributed to the degradation of LiPF₆ during the cycling process.(32, 34, 35) The F₁ₛ peak of the 1AlF₃—5Al₂O₃ NMC electrode shifted after cycling, and the peak can be deconvoluted into two components. The new peak belonged neither to AlF₃ nor to LiF, but belonged to LiAlF₄, and no peak of LiₓPF_{y}LiₓPF_{y}O_{z} emerged. It indicated that during the cycling process, due to the existence of AlF₃ and LiF, and the lithiation of Al₂O₃, instead of being depleted by the electrolyte, a much more stable LiAlF₄ film was formed, which could effectively prevent the electrolyte from decomposing upon cycling. It also explains the reason why 1AlF₃—5Al₂O₃ coating can provide a much longer protection than pure Al₂O₃ coating or AlF₃ coating did.

FIG. 9i-j illustrate the Al₂ₚ XPS spectra of the 1AlF₃—5Al₂O₃ NMC electrode. Two peaks corresponding to AlF₃and Al₂O₃ can be deconvoluted from the Al₂ₚ XPS spectra of fresh coated sample. After 100 cycles of charge-discharge, the peak areas of both AlF₃ and Al₂O₃ decreased sharply, and a strong peak of LiAlF₄ verified that upon cycling; AlF₃ and Al₂O₃ were driven to transform into LiAlF₄. The XPS spectra results of Al₂ₚ are consistent with the results of F₁ₛ.

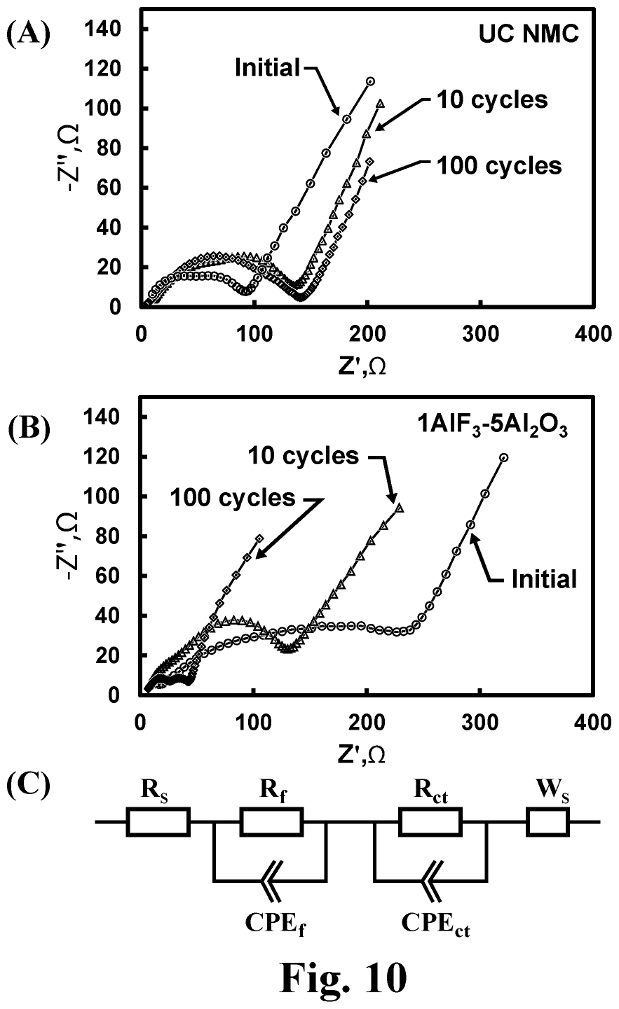

To further understand the origins of electrochemical performance improvement, EIS of UC NMC and 1AlF₃—5Al₂O₃ NMC electrodes were tested, respectively, before charge-discharge and after charge-discharge for 10 and 100 cycles at 2.9 V (vs. Li/Li⁺, as shown in FIG. 10. The impedance spectra (Nyquist plots) consist of two semicircles and an inclined line: the two semicircles are in the high frequency and intermediate frequency ranges, and the inclined line at a constant angle to the abscissa. The first semicircle at the high frequency is attributed to the lithium ions migration through the surface film, and the second semicircle of the intermediate frequency comes from the interfacial charge transfer reaction. The inclined line is the result of lithium ion diffusion into the active host materials.(37, 38)

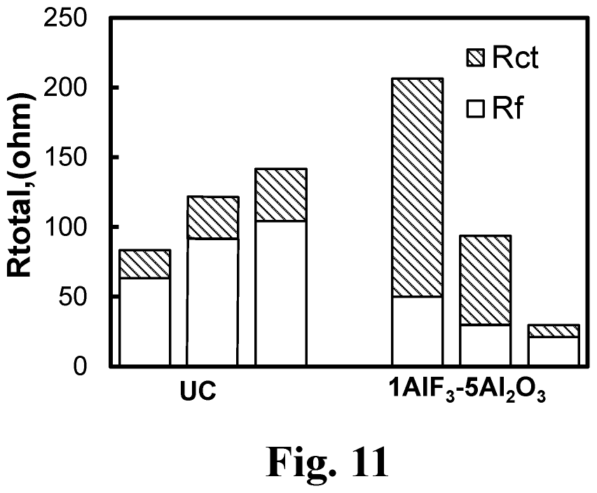

The impedance spectra were fitted using a simplified equivalent circuit. The resistance (Rₛ) represents the uncompensated ohmic resistance. The first pair of resistance (R_{f}) and constant phase element (CPE) represent lithium migration occurring through the surface film region. The second pair of resistance (R_{ct}) and CPE are the indicative of charge-transfer resistance and double layer capacitance. The Warburg impedance (Wₛ), represents the solid-state diffusion reaction. All the electrical parameters in the equivalent circuit were determined from the CNLS (complex nonlinear least-squares) fitting method, as shown in FIG. 11.

For UC NMC, the initial Rf and Rct were about 63 Ω and 21 Ω; after 10 cycles of charge-discharge, the R_{f} and R_{ct} increased to 91 Ω and 28 Ω, respectively, indicating that SPI was formed on the surface of electrodes due to side reactions between the surface and electrolyte. For UC NMC, the smallest values of the charge-transfer resistance and semi-infinite diffusion impedance appeared after formation, while the maximum discharge capacity can be obtained. With continuous cycling, the structural integrity of the Li-rich layered oxides was compromised. As a result, the diffusion impedance and the surface charge-transfer resistance increase gradually, as shown in FIG. 11. For 1AlF₃—5Al₂O₃ NMC, the initial resistance R_{f} (50 Ω) and R_{ct} (156 Ω) were much higher than those of UC NMC, due to the generation of lower conductive LiF during the ALD process, as verified by XPS analysis; however, both of those two resistances decreased along with the charge-discharge cycling, suggesting that electrolyte decomposition at high voltage operation and manganese ion dissolution have been curtailed, which was due to the formation of more stable and conductive LiAlF₄ film; this is consistent with the results of XPS. Furthermore, the suppression of phase transition from layer structure to spinel structure also contributed to the decrease of impedance.

### Coating of NMC Particles

Fluorinated Al₂O₃ was coated on the surface of NMC(Li_{1.2}Mn_{0.54}Co_{0.13}Ni_{0.13}O₂) particles in a fluidized bed atomic layer deposition (ALD) reactor. The results of the electrochemical performance of fluorinated Al₂O₃ coated NMC particles showed the same improvement and tendency as the coatings provided on the electrode surface. Full cells based on coated NMC particles were assembled and compared to fuel cells constructed with un-coated NMC particles. The performance of fluorinated Al₂O₃ coated NMC particles showed improvement in electrochemical performance.

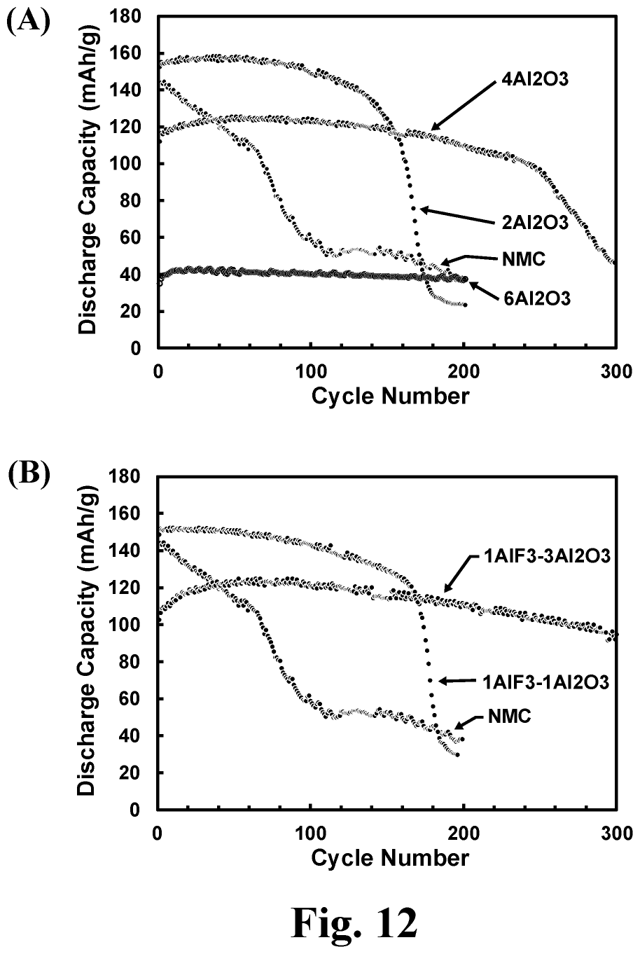

FIG. 12 shows the discharge performance of the half cells based on UC, 2Al₂O₃ (2 cycles of alumina ALD), 4Al₂O₃ (4 cycles of alumina ALD), 6Al₂O₃ (6 cycles of alumina ALD) coated NMC, 1AlF₃—1Al₂O₃ (1 cycle of AlF₃ ALD on top of 1 cycle of alumina ALD), and 1AlF₃—3Al₂O₃ (1cycle of AlF₃ ALD on top of 3 cycles of alumina ALD) coated NMC particles for up to 300 cycles of charge-discharge at a 1 C rate between 2.0 V and 4.8 V at room temperature. The 2Al₂O₃ and 1AlF₃—1Al₂O₃ NMC particles delivered the best initial discharge capacities, ˜154 and ˜151 mAh/g, respectively; The 1AlF₃—1Al₂O₃ NMC particle sample delivered a slightly lower initial capacity but longer cycling span. After 150 cycles of charge-discharge, the capacity retention of 1AlF₃—1Al₂O₃ NMC particles was 85%, as compared to 77% of 2Al₂O₃ NMC particles cycling at the same conditions; by increasing the thickness of Al₂O₃, the cyclic stability could be improved, however, the discharge capacity reduced as a trade-off. It is noticeable that, the effect of extending the cyclic stability by slightly reducing the discharge capacity by slightly fluorinating is better than increasing the thickness of Al₂O₃.

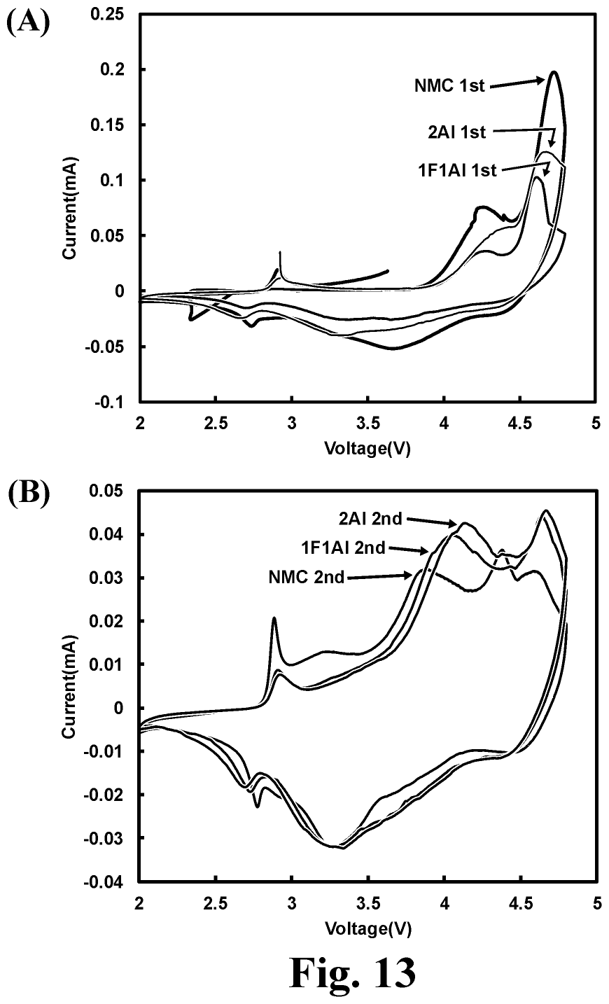

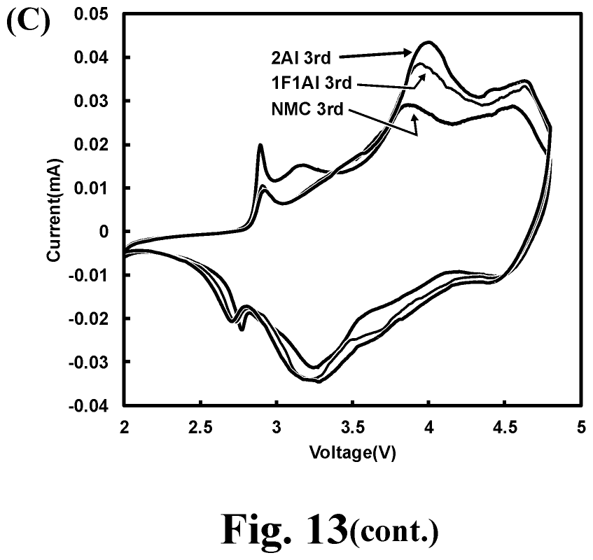

The first three cycles of cyclic voltammograms of uncoated NMC particles, 2Al₂O₃, and 1AlF₃—1Al₂O₃ coated NMC particles were recorded at a sweep rate of 0.02 mV/s between 4.8 and 2.0 V, as shown in FIG. 13, in an attempt to gather information about the individual redox process that occurs during charge and discharge. The overall features of the CVs for coated and uncoated NMC particles, in general, are the same, indicating that the coating layer did not change the inner structure of the host material. In these CVs, the first main anodic peak at approximately 4.0 V on the initial cycle was associated predominantly with Ni oxidation from Ni²⁺ to Ni⁴⁺, and the second peak at higher potential (˜4.6-4.7 V) was associated predominantly with the irreversible electrochemical activation reaction that striped Li₂O from the Li₂MnO₃ component of NMC particles to form MnO₂.(40, 41). Two cathodic peaks are evident on discharge. Although it is impossible to differentiate the reduction processes of the individual Mn, Ni, and Co ions from the obtained data, it is believed that the process at ˜4.5 V may be associated with the occupation of tetrahedral sites by lithium within the extensively delithiated (lithium) layer, in agreement with the reports of Hayley et al.(2007) and Brege'r et al.(2006). By contrast, a reversible redox peak below 3 V is consistent with the lithiation/delithiation of a chemically derived MnO₂ component in the electrode, which is distinct from the MnO₂ component derived electrochemically; the MnO₂ regions have both layered and apparent spinel-like character. However, after the second cycle, the increased peak strength indicated that layered to spinel transformations occurred in localized regions of the structure. Such transformations would be irreversible. For the uncoated NMC particles, the evolution of a dominant reversible redox reaction slightly below 3V after the initial electrochemical activation of the Li₂MnO₃ component of NMC particles above 4.4V occurs at the expense of the redox reaction of the parent layered structure (3.3 V/4.0 V), suggesting that the layered NMC electrode transforms in regions to spinel on cycling to yield a layered-spinel intergrowth structure. However, for 2Al₂O₃ and 1AlF₃—1Al₂O₃ coated NMC particles, the phase transformation between layered to spinel structure is much slower.

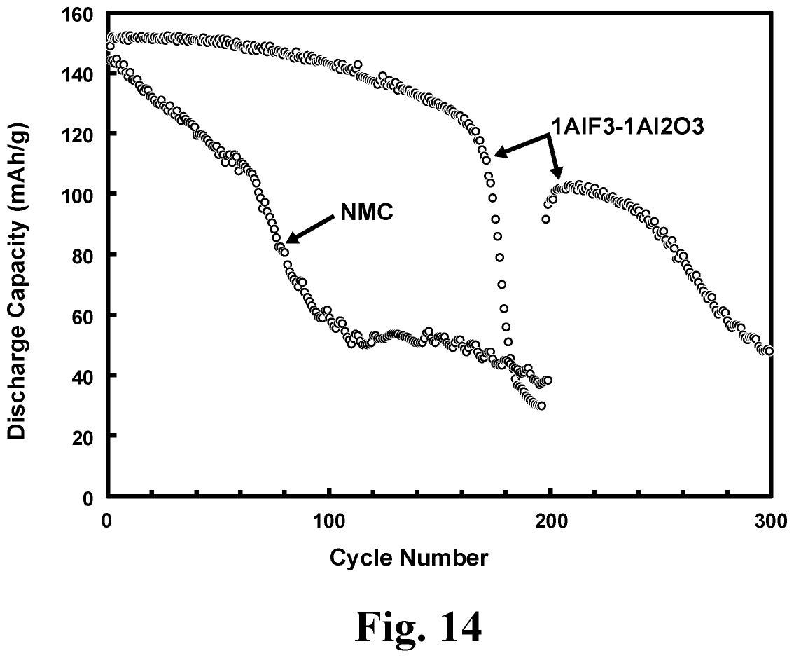

As it is reported that, for Li/NMC cell, the sharp drop in capacity during the cycling process is attributed to the conductivity failure of anode, which is induced by the highly resistive layer with solid electrolyte interface (SEI) entangled with dead Li metal . The Li/NMC batteries assembled from the NMC particles also experienced a sharp decline in battery performance during the charge-discharge process. The 1AlF₃—1Al₂O₃ coated NMC particle-based battery that had been cycled for 200 cycles, was disassembled, taking out the electrode. The electrode was replaced a new lithium foil and the electrochemical performance of newly assembled coin cell was tested (see FIG. 14). It was found that the electrochemical performance can be restored. Due to technical reasons, the electrochemical performance of secondary assembled batteries has decreased significantly. This experiment indirectly showed that it is likely that the degradation of the electrochemical performance was caused by the consumption of the lithium electrode, not the failure of cathode material.

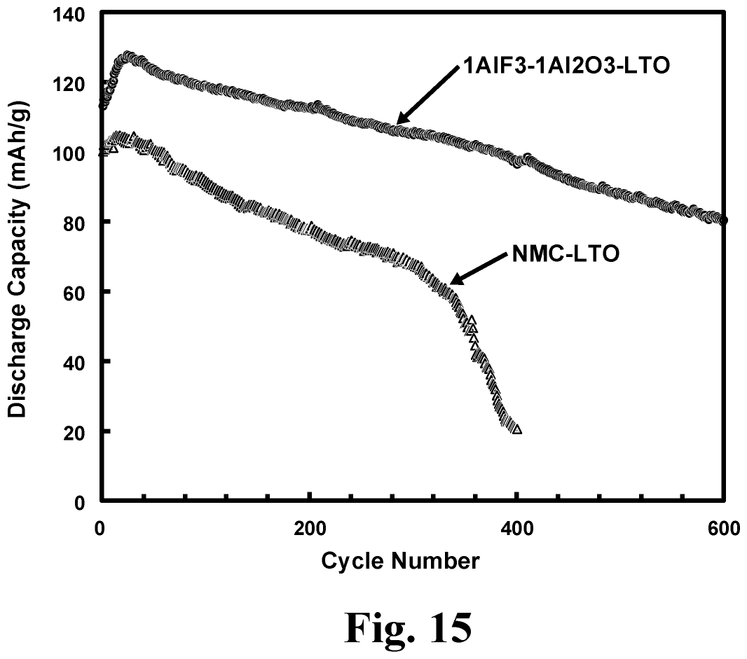

To eliminate the effects of lithium inactivation and study the impact of the coating on the electrochemical performance of the entire battery, UN NMC, and 1AlF₃—1Al₂O₃ coated NMC particles were used as the cathode material, and Li₄Ti₅O₁₂ (LTO) as the anode material to assemble a series of full cells. The electrochemical performance of these batteries was test. The discharge performance of these cells is shown in FIG. 15. Compared to the half-cell, which suffered severe capacity fading within 200 cycles of charge-discharge, 1AlF₃—1Al₂O₃ coated NMC based full cells showed an excellent cyclic stability, after charge-discharge for 600 cycles, the electrochemical performance is much better than that of NMC-LTO.

1. A process for coating the surface of a substrate of a Li-ion battery with a composite thin film of AlF₃ and Al₂O₃ via atomic layer deposition (ALD), the process comprising the following steps in any order:
(a) coating the substrate with from 1 to 10 cycles of Al₂O₃ ALD;
(b) coating the substrate with 1 to 20 cycles of AlF₃ ALD;
to obtain a substrate that is coated with the composite thin film of AlF₃ and Al₂O₃ where composite thin film has a ratio AlF₃:Al₂O₃ from about 20:1 to about 1:10; and
wherein the substrate is made of one or more materials suitable for use in Li-ion batteries.

2. The process of claim 1, wherein the substrate is an electrode or particles.

3. The process of claim 2, wherein when the substrate is an electrode, the electrode is a cathode or an anode.

4. The process of claim 2, wherein the substrate is made from one or more of LCO (LiCO₂), LFP (LiFePO₄), LMO (LiMn₂O₄), NCA (LiNi_{0.8}Co_{0.15}Al_{0.05}O₂), NMC111 (LiNi_{0.3}Mn_{0.3}Co_{0.3}O₂), NMC622 (LiNi_{0.6}Mn_{0.2}Co_{0.2}O₂), or NMC811 (LiNi_{0.8}Mn_{0.1}Co_{0.1}O₂), LMNO (LiMn_{1.5}Ni_{0.5}O₄), Li-rich NMC (Li_{1.2}Mn_{0.54}Co_{0.13}Ni_{0.13}O₂), or a Ni-rich NMC.

5. The process of claim 4 wherein the substrate is made from LMNO (LiMn_{1.5}Ni_{0.5}O₄) or Li-rich NMC (Li_{1.2}Mn_{0.54}Co_{0.13}Ni_{0.13}O₂).

6. The process of claim 4 wherein the substrate is made from LMNO (LiMn_{1.5}Ni_{0.5}O₄).

7. The process of claim 4 wherein the substrate is made from LMNO Li-rich NMC (Li_{1.2}Mn_{0.54}Co_{0.13}Ni_{0.13}O₂).

8. The process of claim 4 wherein the substrate is made from the Ni-rich NMC.

9. The process of claim 8 wherein the Ni-rich NMC is NMC111 (LiNi_{0.3}Mn_{0.3}Co_{0.3}O₂), NMC622 (LiNi_{0.6}Mn_{0.2}Co_{0.2}O₂) or NMC811 (LiNi_{0.8}Mn_{0.1}Co_{0.1}O₂).

10. The process of claim 8. wherein the Ni-rich NMC is NMC622 (LiNi_{0.6}Mn_{0.2}Co_{0.2}O₂).

11. The process of claim 8 wherein the wherein the Ni-rich NMC is NMC811 (LiNi_{0.8}Mn_{0.1}Co_{0.1}O₂).

12. The process of claim 1, wherein steps (a) and/or (b) are carried out at 100° C.

13. The process of claim 1, wherein in step (b) the number of cycles is from 1 and 10 cycles.

14. The process of claim 1, wherein the number of cycles in step (a), (b), or (a) and (b) are independently in the range between 1 and 5 cycles.

15. The process of claim 14 wherein in step (a) the number of cycles is from 1 to 2, and in step (b) the number of cycles is from 1 to 5.

16. A composition obtained by the process of claim 1.

17. The composition of claim 16, wherein the ratio AlF₃:Al₂O₃ is from about 1:8 to about 8:1.

18. The composition of claim 17, wherein the ratio AlF₃:Al₂O₃ is about 1:5.

19. Use of the composition of claim 16 to improve the cycling stability of a Li-ion battery, the use comprising the step of incorporating the composition into the Li-ion battery instead of uncoated substrate, resulting in improvement of the cycling stability of the Li-ion battery.

20. The use of claim 19, wherein the use further results in reduction of voltage attenuation of electrodes of the Li-ion battery by suppressing side reactions between the electrolyte and electrode.

21. The use of claim 19, wherein the use further results in inhibiting the transformation of layered Li₂MnO₃ into a spinel-like phase and in decreasing impedance.

22. The use of claim 19, wherein the use further results in reduction of the voltage fade problem due to aging along with the structural transformation during charge-discharge process.
